(19) United States
(12) Patent Application Publication
(10) Pub. No.: US 2013/0276849 A1
(43) Pub. Date: Oct. 24, 2013

(54) TEG-POWERED COOLING CIRCUIT FOR THERMOELECTRIC GENERATOR

(71) Applicant: GENTHERM, INCORPORATED, Northville, MI (US)

(72) Inventors: Dmitri Kossakovski, South Pasadena, CA (US); Douglas T. Crane, Altadena, CA (US); Vladimir Jovovic, Pasadena, CA (US)

(73) Assignee: Gentherm, Incorporated, Northville, MI (US)

(21) Appl. No.: 13/794,108

(22) Filed: Mar. 11, 2013

Related U.S. Application Data
(60) Provisional application No. 61/635,738, filed on Apr. 19, 2012.

(51) Int. Cl. H01L 35/32

(52) U.S. Cl. CPC H01L 35/32
USPC 136/201; 136/205; 123/2

(57) ABSTRACT

A system includes at least one thermoelectric generator configured to generate electricity in response to a temperature difference across at least a portion of the at least one thermoelectric generator. The system further includes at least one fluid conduit in thermal communication with the at least one thermoelectric generator. The at least one fluid conduit is configured to have at least one working fluid flow through the at least one fluid conduit. The system further includes at least one device configured to direct the at least one working fluid through the at least one fluid conduit. The at least one device is powered by at least a portion of the electricity generated by the at least one thermoelectric generator.

### CROSS-REFERENCE TO RELATED APPLICATIONS

This application claims the benefit of U.S. Provisional Application No. 61/635,738 filed Apr. 19, 2012, which is incorporated herein in its entirety by reference.

### BACKGROUND

1. Field of the Application

The present application relates generally to systems that include thermoelectric power generation.

2. Description of the Related Art

Thermoelectric generators (TEGs) convert heat flux (e.g., thermal energy, temperature difference, temperature gradient) into electricity. In some applications, the heat (e.g., thermal energy, flux, etc.) is a by-product of an energy intensive process, such as internal combustion (e.g., within an engine) or industrial manufacturing of metals. A portion of the heat flowing through the TEG is converted into electricity, while the rest (unconverted heat) exits the TEG and is removed. Heat removal is typically performed by a heat transfer medium (e.g., fluid) such as air or a liquid that carries or moves it away from the TEG. Typically, the heat transfer medium is actively circulated by fans, pumps or other devices.

### SUMMARY

In some embodiments, a system is provided that comprises at least one thermoelectric generator. The thermoelectric generator is configured to generate electricity in response to a temperature difference across at least a portion of the at least one thermoelectric generator. The system further comprises at least one fluid conduit in thermal communication with the at least one thermoelectric generator. The at least one fluid conduit is configured to have at least one working fluid flow through the at least one fluid conduit. The system further comprises at least one device configured to direct the at least one working fluid through the at least one fluid conduit. The at least one device is powered by at least a portion of the electricity generated by the at least one thermoelectric generator.

In some embodiments, the at least one working fluid comprises a coolant fluid. The at least one fluid conduit comprises a coolant loop. The at least one device is configured to circulate the coolant fluid through the coolant loop.

In some embodiments, the at least one working fluid and the at least one fluid conduit are configured to remove at least some waste heat from the at least one thermoelectric generator. In some embodiments, the at least one fluid conduit is in thermal communication with a cold side of the at least one thermoelectric generator.

In some embodiments, the at least one device comprises at least one of the group consisting of: an electrically-powered pump, an electrically-powered fan, and an electrically-powered valve. The system can comprise at least one control circuit configured to be powered by the at least one thermoelectric generator and to selectively provide power to the at least one device from the at least one thermoelectric generator.

In some embodiments, the at least one device is configured to respond to the portion of the electricity generated by the at least one thermoelectric generator being greater than a predetermined level by directing the at least one working fluid through the at least one fluid conduit. The at least one device is further configured to respond to the portion of the electricity generated by the at least one thermoelectric generator being less than the predetermined level by inhibiting the at least one working fluid from flowing through the at least one fluid conduit.

In some embodiments, the predetermined level is either an electric voltage level or an electric current level. The at least one device is configured to automatically shut off when the portion of the electricity generated by the at least one thermoelectric generator falls below the predetermined level.

In certain embodiments, the at least one device is configured to respond to at least one temperature of the at least one thermoelectric generator (e.g., a hot side temperature of the TEG, a cold side temperature of the TEG) by directing the at least one working fluid through the at least one fluid conduit when the at least one temperature is greater than a predetermined value. The at least one device can be further configured to respond to the at least one temperature of the at least one thermoelectric generator by inhibiting the at least one working fluid from flowing through the at least one fluid conduit when the at least one temperature of the at least one thermoelectric generator is less than the predetermined level.

In some embodiments, the system further comprises a heat source configured to provide heat that contributes to the temperature difference across the portion of the at least one thermoelectric generator. In some embodiments, the heat source comprises at least one of the group consisting of: an internal combustion engine, an industrial manufacturing process, and a turbine. In some embodiments, the at least one working fluid and exhaust gas from the internal combustion engine generate the temperature difference across the portion of the at least one thermoelectric generator.

In some embodiments, the heat source generates heat during a first operational mode and the heat source comprises stored heat during a second operational mode. In some embodiments, the heat source comprises an internal combustion engine that performs combustion during the first operational mode and that does not perform combustion during the second operational mode.

In some embodiments, during at least a portion of the second operational mode, the stored heat contributes to the temperature difference across the portion of the at least one thermoelectric generator. The at least one device directs sufficient flow of the at least one working fluid through the at least one fluid conduit thereby preventing thermal damage to the at least one thermoelectric generator by the stored heat.

In some embodiments, the provided heat contributes to the temperature difference across the portion of the at least one thermoelectric generator during at least a portion of the first operational mode. The at least one device is wholly powered by the portion of the electricity generated by the at least one thermoelectric generator.

In some embodiments, a method of operating a system comprises at least one thermoelectric generator in thermal communication with a heat source and in thermal communication with at least one fluid conduit. The at least one fluid conduit is configured to have at least one working fluid flow through the at least one fluid conduit. The heat source generates heat in a first operational mode and comprises stored heat during a second operational mode. The method comprises generating electricity using the at least one thermoelectric generator in response to a temperature difference across at least a portion of the at least one thermoelectric generator. The method further comprises powering at least one device by at least a portion of the electricity generated by the at least one thermoelectric generator. The at least one device is configured to direct the at least one working fluid through the at least one fluid conduit.

In some embodiments, the system in the second operational mode does not generate heat. In some embodiments, during at least a portion of the second operational mode, the stored heat contributes to the temperature difference across the portion of the at least one thermoelectric generator. Directing the at least one working fluid through the at least one fluid conduit can comprise removing heat from the at least one thermoelectric generator.

In some embodiments, removing heat from the at least one thermoelectric generator prevents catastrophic failure of the at least one thermoelectric generator due to overheating.

In some embodiments, the system comprises at least one battery. Powering the at least one device comprises reducing or eliminating use of electricity from the at least one battery to power the at least one device.

In some embodiments, powering the at least one device by the portion of the electricity generated by the at least one thermoelectric generator occurs during both the first operational mode and the second operational mode.

In some embodiments, the method further comprises directing the at least one working fluid through the at least one fluid conduit when a temperature of the at least one thermoelectric generator is greater than a predetermined level. The method can further comprise inhibiting the at least one working fluid from flowing through the at least one fluid conduit when the temperature of the at least one thermoelectric generator is less than the predetermined level.

In some embodiments, the method further comprises directing the at least one working fluid through the at least one fluid conduit while the portion of the electricity generated by the at least one thermoelectric generator is greater than a predetermined level. The method can further comprise inhibiting the at least one working fluid from flowing through the at least one fluid conduit while the portion of the electricity generated by the at least one thermoelectric generator is less than the predetermined level.

In some embodiments, the predetermined level is either an electric voltage level or an electric current level. Inhibiting the at least one working fluid from flowing through the at least one fluid conduit comprises automatically shutting off the at least one device when the portion of the electricity generated by the at least one thermoelectric generator falls below the predetermined level.

### BRIEF DESCRIPTION OF THE DRAWINGS

Various embodiments are depicted in the accompanying drawings for illustrative purposes, and should in no way be interpreted as limiting the scope of the thermoelectric devices, systems, or methods described herein. In addition, various features of different disclosed embodiments can be combined with one another to form additional embodiments, which are part of this disclosure. Any feature or structure can be removed, altered, or omitted. Throughout the drawings, reference numbers may be reused to indicate correspondence between reference elements.

FIG. 1 schematically illustrates an example conventional system.

FIG. 2 schematically illustrates an example system utilizing residual heat in accordance with certain embodiments described herein.

FIG. 3 schematically illustrate san example system utilizing an exhaust gas in accordance with certain embodiments described herein.

FIG. 4 is a generalized block flowchart of an example method in accordance with certain embodiments described herein.

### DETAILED DESCRIPTION

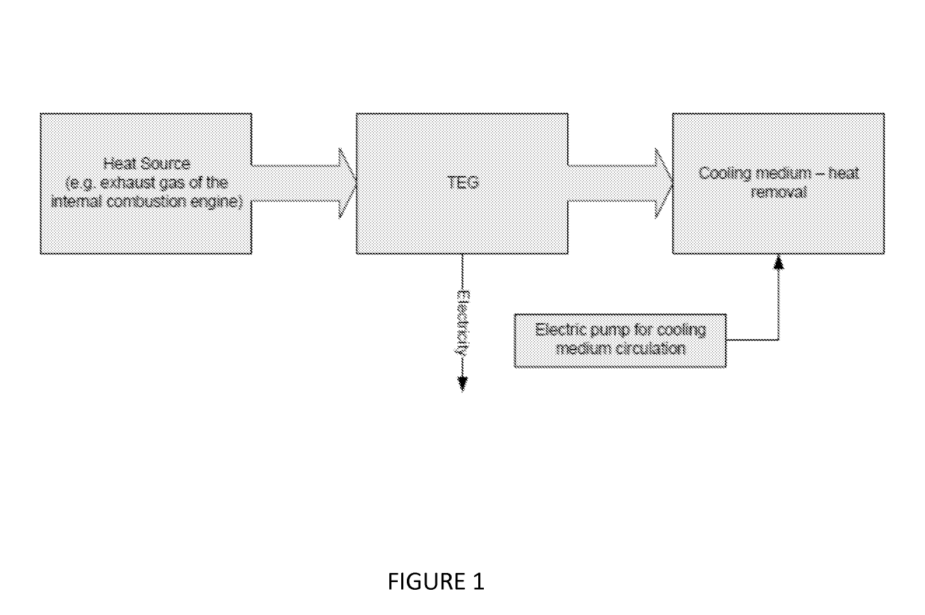

In conventional systems, as depicted in FIG. 1, a TEG receives heat from a heat source (e.g., exhaust gas from an internal combustion engine). A cooling medium removes waste heat from the TEG and the TEG generates electricity. For example, TEGs have been used as energy recovery devices in automobiles with internal combustion engines. A pump (or other device) circulates water or a water-glycol mix through the TEG on the cold side.

When the heat source (e.g., engine) is turned off, there can still be residual heat accumulated in the heat source (e.g., car exhaust system), other portions of the system (e.g., pipes, manifolds, heat exchangers, etc.), and/or the TEG. If a mechanical pump is used to circulate the cooling medium (e.g., for cooling in cars with an internal combustion engine), the mechanically-actuated pump will stop working after the engine is shut off, potentially resulting in damage to the TEG due to being exposed to high temperatures from the residual heat while having the cooling circulation terminated. Many modern cars instead use electric water pumps to provide circulation of the cooling medium, and these pumps are powered by a battery. The water (or other cooling medium) can be kept circulating in the cooling circuit by continuing to power the pump after the heat source (e.g., engine) is turned off to avoid thermal damage to the TEG. However, the electric power for the pump is taken from the battery, therefore depleting it.

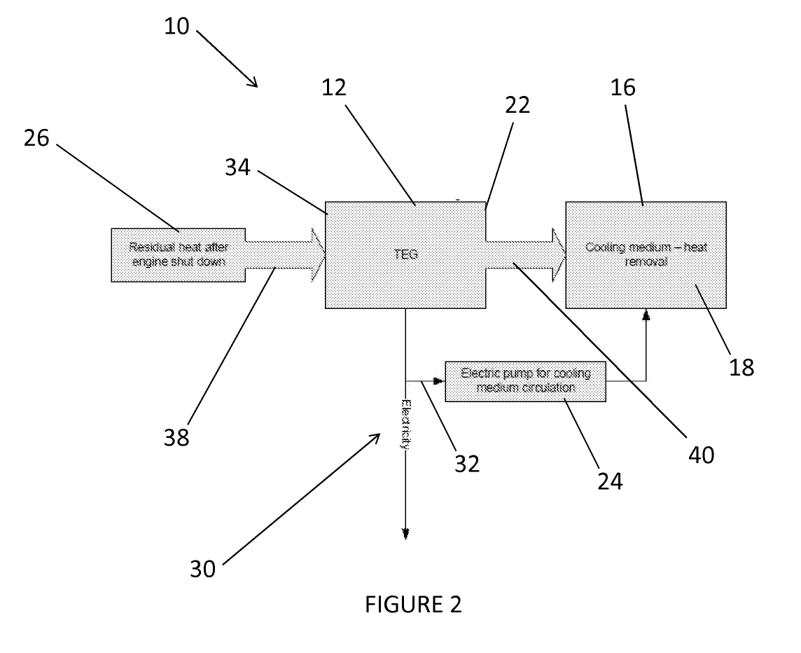

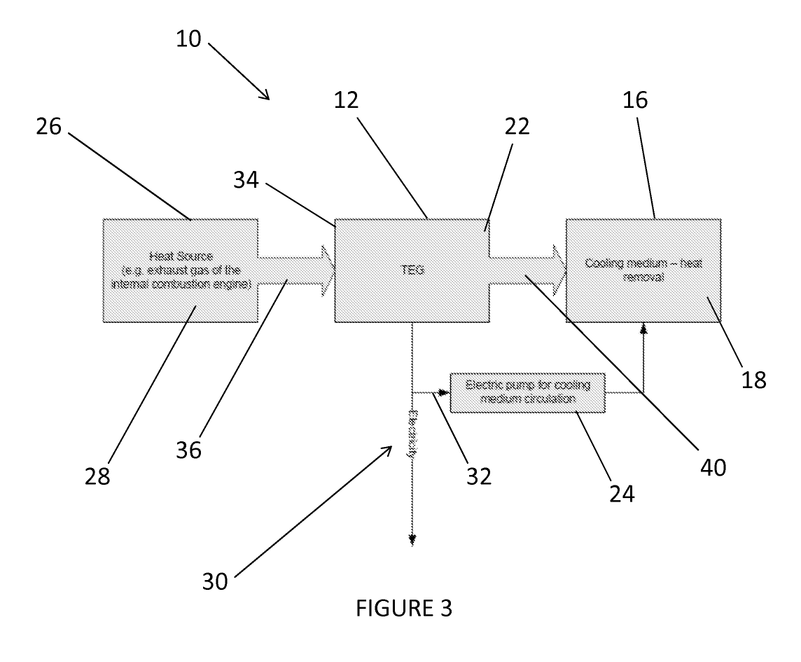

In certain embodiments described herein, the electric power consumed by the pump is minimal compared to the amount of electricity the TEG is producing. In certain embodiments described herein, the TEG is used to power the pump or other device (e.g., for fluid circulation) as schematically illustrated in FIGS. 2 and 3. Such a configuration can accomplish one or more of the following: (i) preventing catastrophic failure of the TEG due to overheating on the cold side; (ii) reducing the drain of electricity from the battery; and (iii) simplifying the control system resulting in lower cost and higher reliability.

In some embodiments, a system is provided that comprises at least one TEG configured to be responsive to generate electricity in response to a temperature difference across at least a portion of the at least one TEG. This temperature difference can be the result of heat (e.g., thermal energy, heat flux) applied to a portion of the at least one TEG. The system further comprises a circuit (e.g., a cooling loop, fluid conduit, coolant loop, etc.) configured to have a heat transfer medium (e.g., working fluid) flowing in the circuit. The heat transfer medium is configured to remove waste heat (e.g., residual heat, stored heat, heat unconverted into electricity, etc.) from the TEG. The system further comprises at least one device (e.g., an electrically-driven actuator) powered by electricity generated by the at least one TEG configured to circulate the heat transfer medium in and/or through the circuit.

The term “thermal communication” is used herein in its broad and ordinary sense, describing two or more components that are configured to allow heat transfer from one component to another. For example, such thermal communication can be achieved, without loss of generality, by snug contact between surfaces at an interface; one or more heat transfer materials or devices between surfaces; a connection between solid surfaces using a thermally conductive material system, wherein such a system can include pads, thermal grease, paste, one or more working fluids, or other structures with high thermal conductivity between the surfaces (e.g., heat exchangers); other suitable structures; or combinations of structures. Substantial thermal communication can take place between surfaces that are directly connected (e.g., contact each other) or indirectly connected via one or more interface materials.

FIGS. 2-3 schematically illustrate an example system 10 in accordance with certain embodiments described herein. In certain embodiments, the system 10 comprises at least one thermoelectric generator (TEG) 12. The thermoelectric generator 12 is configured to generate electricity 30 in response to a temperature difference across at least a portion of the at least one thermoelectric generator 12. The system 10 further comprises at least one fluid conduit 16 in thermal communication with the at least one thermoelectric generator 12. The at least one fluid conduit 16 is configured to have at least one working fluid 18 flow through the at least one fluid conduit 16. The system 10 further comprises at least one device 24 configured to direct the at least one working fluid 18 through the at least one fluid conduit 16. The at least one device 24 is powered by at least a portion of the electricity generated (as indicated by arrow 32) by the at least one thermoelectric generator 12.

In certain embodiments, the system 10 can be a component of a vehicle and can utilize engine coolant as the at least one working fluid 18. For example, the at least one working fluid 18 can flow through a radiator configured to cool an engine of the vehicle and can also flow through the at least one fluid conduit 16 (e.g., loop) in thermal communication with the at least one TEG 12. In certain embodiments, the at least one working fluid 18 is used to cool the powertrain of the vehicle. In certain other embodiments, the at least one working fluid 18 may be cooled by routing it through a heat exchanger attached or encased within the vehicle fuel tank.

As described herein, a system can include one or more TEGs 12 (e.g., a single TEG or a plurality of TEGs). A TEG 12 can include one or more thermoelectric (TE) elements (e.g., p- or n-type), TE materials, TE assemblies and/or TE modules. In some embodiments, a TEG 12 comprises a hot side 34 and a cold side 22 (e.g., opposite the hot side 34). In some embodiments, the hot side 34 and cold side 22 can be referred to, respectively, as a main surface and waste surface, or a heating surface and a cooling surface. The terms “hot”, “cold”, “heating”, and “cooling” signify relative temperatures of the sides, surface, or portions of the TEG 12 so labeled, and are not interpreted as signifying a particular temperature or range of temperatures. Certain non-limiting embodiments are described below.

In some embodiments, the TEG 12 is configured to use the temperature difference or gradient between two fluids in thermal communication with the respective hot side 34 and cold side 22 of the TEG 12 to produce electrical power via thermoelectric materials. The cold side 22 can be in thermal communication with the at least one fluid conduit 16 and the hot side 34 can be in thermal communication with a heat source 26, such that the TEG 12 can receive heat flow from the heat source 26. The heat flux can pass or flow from one side of the TEG 12 to another side. For example, the heat can flow from the hot side 34 to the cold side 22 of the TEG 12.

In certain embodiments, the at least one TEG 12 comprises a first heat exchanger (not shown) in thermal communication with the hot side 34 of the at least one thermoelectric generator 12 and with a second working fluid (e.g., exhaust gas, etc.) in thermal communication with the heat source 26. The at least one TEG 12 can comprise a second heat exchanger (not shown) in thermal communication with the cold side 22 of the at least one TEG 12 and with the at least one working fluid 18. In certain embodiments, the second working fluid and the at least one working fluid 18 each comprise a gas. In certain embodiments, the second working fluid and the at least one working fluid 18 each comprise a liquid. In certain embodiments, one of the second working fluid and the at least one working fluid 18 comprises a gas and the other of the second working fluid and the at least one working fluid 18 comprises a liquid. The first working fluid 18 and the second working fluid can be the same phase (e.g., both liquid) or can be different (e.g., liquid and gas).

In some embodiments, the at least one fluid conduit 16 (e.g., fluid circuit, cooling loop, or coolant conduit) is in thermal communication with the at least one TEG 12 and is configured to have the at least one working fluid 18 flow therein. In certain embodiments, the at least one fluid conduit 16 comprises a tube, pathway, channel, pipe, circuit, loop (e.g., open loop or closed loop) or other structure configured to allow the at least one working fluid 18 to flow therethrough. In certain embodiments, the at least one working fluid 18 can flow only once through the at least one conduit 16, while in other certain embodiments, the at least one working fluid 18 can flow repeatedly through the at least one conduit 16. For example, the at least one fluid conduit 16 can comprise a coolant loop.

In some embodiments, the at least one working fluid 18 comprises gas, liquid, or a combination of gas and liquid. For example, the at least one working fluid 18 can comprise a coolant fluid (e.g., water, water-glycol mix, radiator fluid, etc.). The first working fluid 18 may comprise ambient air, liquid coolant, another flowing or stagnant fluid, or a combination of fluids. The first working fluid 18 may be contained within the at least one fluid conduit 16 (e.g., a channel of a fluid circuit or loop), and the first working fluid 18 may be directed through the at least one fluid conduit 16 to establish substantial thermal contact (e.g., in thermal communication) with the at least one TEG 12, thereby facilitating the transfer of thermal energy or heat between the cold side 22 of the at least one TEG 12 and the first working fluid 18. Movement of the first working fluid 18 can increase the transfer rate of thermal energy or heat from the at least one TEG 12 to the first working fluid 18, thereby increasing the temperature differential between the hot side 34 and the cold side 22 of the at least one TEG 12. A heat exchanger (not shown) may likewise increase the transfer of thermal energy between the cold side 22 of at least one TEG 12 and the first working fluid 18. For example, fins may increase the surface area from which thermal energy may escape from the cold side 22 into the surrounding first working fluid 18.

In some embodiments, the at least one working fluid 18 and the at least one fluid conduit 16 are configured to remove at least some waste heat (e.g., residual heat, stored heat, unconverted heat, thermal inertia, etc.) from the at least one TEG 12. In some embodiments, the at least one fluid conduit 16 is in thermal communication with a cold side 22 of the at least one TEG 12.

The at least one device 24 is configured to direct the at least one working fluid 18 through the at least one fluid conduit 16. The at least one device 24 can comprise an electrically-powered flow regulator (e.g., actuator, fan, pump, valve, fluid bypass), or other means or combination of means. For example, in some embodiments, the at least one device 24 comprises at least one of the group consisting of: an electrically-powered pump, an electrically-powered fan, and an electrically-powered valve. In certain embodiments, the at least one device 24 is adjustable to control flow of the at least one working fluid 18 in the at least one fluid conduit 16. In certain such embodiments, the at least one device 24 comprises one or more valves that are adjustable to selectively place the at least one working fluid 18 in thermal communication with the at least one TEG 12. As illustrated in FIGS. 2 and 3, the at least one device 24 is powered by at least some of the electricity generated by the at least one TEG 12.

In some embodiments, the at least one device 24 is configured to respond to the portion of the electricity generated by the at least one TEG 12 being greater than a predetermined level by directing the at least one working fluid 18 through the at least one fluid conduit 16. The at least one device 24 is further configured to respond to the portion of the electricity generated by the at least one TEG 12 being less than the predetermined level by inhibiting the at least one working fluid 18 from flowing through the at least one fluid conduit 16. For example, the at least one device 24 can be configured to circulate the working fluid 18 (e.g., coolant fluid) through the fluid conduit 16 (e.g., coolant loop) when the portion of the electricity is greater than the predetermined level. The at least one device 24 can also be configured to inhibit the working fluid 18 from flowing through the fluid conduit 16 when the portion of the electricity is less than the predetermined level.

In some embodiments, the predetermined level is either an electric voltage level or an electric current level. The at least one device 24 can be configured to automatically shut off when the portion of the electricity generated by the at least one TEG 12 and received by the at least one device 24 falls below the predetermined level. For example, the system 10 can comprise a soft shutdown mode (e.g., engine off mode, shutdown, power-off or disconnected) in which the at least one TEG 12 generates more than enough electricity (at least initially after the heat source is turned off) to operate the at least one device 24. In the soft shutdown mode, at least some of the electricity generated by the at least one TEG 12 after the heat source is turned off is used to power the at least one device 24. As the heat source cools after having been turned off, the electricity generated by the at least one TEG 12 lessens, eventually reaching a level which is no longer sufficient to operate the at least one device 24. With the heat source cooled to a level that no longer poses a risk of damage to the at least one TEG 12, the electricity generated by the at least one TEG 12 is insufficient to run the at least one device 24, and the at least one device 24 ceases directing the at least one working fluid 18 through the at least one fluid conduit 16. In some embodiments, such a system 10 can be configured to use electricity generated by the at least one TEG 12 to power the at least one device 24 during regular (e.g., engine-on, power-on or connected) TEG operation as well, as illustrated in FIG. 3 and discussed further below.

In some embodiments, the system 10 can further comprise at least one controller (e.g., at least one control circuit) configured to be powered by the at least one TEG 12 and to selectively provide power to the at least one device 24 from the at least one TEG 12. For example, the at least one control circuit (e.g., one or more processors, computers, or microcontrollers) can be in operative communication with the at least one device 24 or can be a component of the at least one device 24.

In some embodiments, the at least one device 24 can comprise at least one controller or control circuit (e.g., one or more processors, computers, or microcontrollers) and at least one sensor (e.g., temperature sensor) to sense the temperature of the hot side 34 and/or cold 22 side of the at least one TEG 12. The at least one controller or control circuit can then control the at least one device 24 to direct the at least one working fluid 18 through the at least one fluid conduit 16 or to inhibit the at least one working fluid 18 from flowing therein depending on the temperature of the hot side 34 and/or cold side 22 of the at least one TEG 12.

In some embodiments, the at least one device 24 is configured to respond to at least one temperature of the at least one TEG 12 (e.g., a temperature of the hot side 34 of the TEG 13, a temperature of the cold side 22 of the TEG 12) by directing the at least one working fluid 18 through the at least one fluid conduit 16 when the at least one temperature is greater than a predetermined value. The at least one device 24 can be further configured to respond to the at least one temperature of the at least one TEG 12 by inhibiting the at least one working fluid 18 from flowing through the at least one fluid conduit 16 when the at least one temperature of the at least one TEG 12 is less than the predetermined level. In some embodiments, the predetermined level is a temperature level that is safe (e.g., that avoids catastrophic failure) for the at least one TEG 12 to operate.

In some embodiments, the at least one device 24 can comprise at least one controller (e.g., one or more processors, computers, or microcontrollers) and at least one sensor (e.g., electric voltage sensor, electric current sensor, electric power sensor) to sense the amount of electricity received from the at least one TEG 12. The at least one controller can then control the at least one device 24 to direct the at least one working fluid 18 through the at least one fluid conduit 16 or to inhibit the at least one working fluid 18 from flowing therein depending on the amount of electricity received. In certain other embodiments, the at least one device 24 does not comprise a controller or sensors, but instead is configured to (i) only operate (e.g., direct the at least one working fluid 18 through the at least one fluid conduit 16) when sufficient electric power is received and (ii) to not operate (e.g., to inhibit flow of the at least one working fluid 18 from flowing through the at least one fluid conduit 16) when less than the sufficient electric power for operation is received. In certain embodiments, the system 10 can comprise at least one controller and at least one sensor to sense the amount of electricity generated by the at least one TEG 12, with the at least one controller being responsive to signals from the sensors to send appropriate control signals to the at least one device 24.

In some embodiments, the system 10 further comprises the heat source 26 (e.g., exhaust gas from an internal combustion engine, waste heat generated by an industrial process such as manufacturing, residual heat from a turbine, or any other source that may produce heat then stop producing heat as a result of an extrinsic reason) configured to provide heat that contributes to the temperature difference across the portion of the at least one TEG 12. In some embodiments, the heat source 26 comprises an internal combustion engine 28. In certain embodiments, the exhaust gas from the internal combustion engine 28 can carry or transfer heat from the internal combustion engine 28 to the at least one TEG 12. In certain embodiments, heat from internal combustion engine 28 can flow to the at least one TEG 12 through thermally conductive portions of the system 10. In some embodiments, the at least one working fluid 18 and the exhaust gas from the internal combustion engine 28 generate the temperature difference across the portion of the at least one TEG 12.

In some embodiments, the heat source 26 generates heat as indicated by arrow 36 during a first operational mode (e.g., engine on, power on or connected, etc.) and the heat source 26 comprises stored heat (e.g., residual heat, thermal inertia, unconverted heat, waste heat, etc.) as indicated by arrow 38 during a second operational mode (e.g., engine-off, shutdown, power-off or disconnected, etc.). In some embodiments, the heat source 26 comprises an internal combustion engine 28 that performs combustion or a power cycle during the first operational mode (e.g., engine on) and that does not perform combustion or a power cycle during the second operational mode (e.g., engine off). For example, during the second operational mode, additional heat is not generated directly by a power cycle or stroke of the internal combustion engine 28 because the internal combustion engine 38 is shutdown or “off” in the second operational mode. In the context of an internal combustion engine, and as similarly discussed herein, the “first operational mode” refers to the “engine on” mode and the “second operation mode” refers to the “engine off” mode.

FIG. 2 schematically illustrates an example system 10 utilizing the stored heat in accordance with certain embodiments described herein. In some embodiments, during at least a portion of the second operational mode, the stored heat contributes to the temperature difference across the portion of the at least one TEG 12. The at least one device 24 can direct sufficient flow of the at least one working fluid 18 through the at least one fluid conduit 16, during the second operational mode, thereby preventing thermal damage to the at least one TEG 12 by the stored heat. In some embodiments, this type of configuration can become a self-regulating system, e.g., the cooling liquid circulates when the TEG requires cooling. Under such an arrangement, the system 10 has a built-in soft shutdown mechanism—wherein the TEG is operable to cool itself and avoid catastrophic overheating. For example, in configurations in which the stored heat after the engine is shut off would be sufficiently large to inflict thermal damage to the at least one TEG 12, the stored heat can be used by the system 10 to generate sufficient electrical power to power the at least one device 24 to keep the at least one working fluid 18 flowing and to remove waste heat from the at least one TEG 12. In some embodiments, when the stored heat has been reduced to a level that does not inflict thermal damage to the at least one TEG 12, the electric power generated by the at least one TEG 12 can be too low to keep the at least one working fluid 18 flowing. In some embodiments, the stored heat can be used by the system 10 to generate more electrical power than is sufficient to power the at least one device 24 during the second operational mode. The additional generated power can be used to power other systems or devices as well.

FIG. 3 schematically illustrates an example system 10 utilizing an exhaust gas in accordance with certain embodiments described herein. In some embodiments, the heat provided by the exhaust gas contributes to the temperature difference across the portion of the at least one TEG 12 during at least a portion of the first operational mode. The at least one device 24 can be wholly powered by the portion of the electricity generated by the at least one TEG 12. For example, the at least one device 24 can be partially or wholly decoupled from the other electrical components or subsystems of the system 10, making the cooling circuit (including the at least one device 24) a self-contained subsystem. Certain such embodiments can advantageously decrease system complexity and increase fault-tolerance.

In some embodiments, a method is provided for operating a system comprising at least one thermoelectric generator 12 in thermal communication with a heat source 26 and in thermal communication with at least one fluid conduit 16. For example, operating the system can comprise powering a cooling system for a TEG.

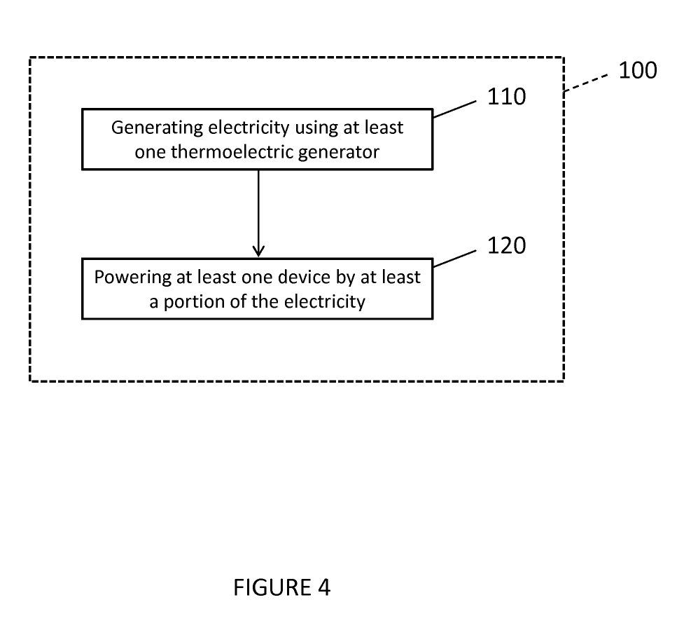

FIG. 4 is a generalized block flowchart of an example method 100 of operating a system 10 in accordance with certain embodiments described herein. The system 10 can comprise at least one TEG 12 in thermal communication with a heat source 26 and in thermal communication with at least one fluid conduit 16 configured to have at least one working fluid 18 flow through the at least one fluid conduit 16. The heat source 26 can generate heat in a first operational mode and can comprise stored heat during a second operational mode. While the following description of the example method 100 includes reference to the structure shown in FIGS. 2 and 3 and described above, the method 100 can be practiced using other structures, components, and configurations.

In an operational block 110, the method 100 comprises generating electricity using the at least one TEG 12 in response to a temperature difference across at least a portion of the at least one TEG 12. In an operational block 120, the method 100 further comprises powering at least one device 24 by at least a portion of the electricity generated by the at least one TEG 12. The at least one device 24 is configured to direct the at least one working fluid 18 through the at least one fluid conduit 16.

In some embodiments, the system 10 in the second operational mode does not generate heat. For example, when used in conjunction with an internal combustion engine, the internal combustion engine is off in the second operational mode. In some embodiments, during at least a portion of the second operational mode, the stored heat (e.g., residual heat in the internal combustion engine) contributes to the temperature difference across the portion of the at least one TEG 12. Directing the at least one working fluid 18 through the at least one fluid conduit 16 can comprise removing heat from the at least one TEG 12.

In some embodiments, removing heat from the at least one TEG 12 prevents catastrophic failure of the at least one TEG 12 due to overheating. For example, after turning off the system (e.g., internal combustion engine) from which heat is being converted into electricity, failure to remove the heat (e.g., waste heat, residual heat, etc. from the internal combustion engine) can result in overheating of the TEG and, potentially, damaging it. Therefore, maintaining cooling during soft shutdown of a system or device can be important for the usability of and lifecycle of the TEGs of such systems or devices. As discussed above, the residual heat accumulated in the vehicle exhaust system and the at least one TEG 12 can be removed by continuing to power the pump to circulate the water (or other cooling medium) in the cooling circuit to avoid thermal damage to the TEG. The electric power for the pump is advantageously taken from the electric power generated by the TEG.

In some embodiments, the system 10 comprises at least one battery. Powering the at least one device 24 comprises reducing or eliminating use of electricity from the at least one battery to power the at least one device 24. For example, due to thermal inertia, there can still be thermal flux flowing through the TEG after engine shutdown, and the TEG can generate electric energy in response to this thermal flux. Therefore, instead of using electric power from the battery to drive the at least one device 24 (e.g., pump), certain embodiments use this TEG-generated electric power to drive the at least one device 24.

Similarly, in some embodiments, the principle can be used in other systems as well. For example, some turbo-molecular pumps can generate electricity if the power is shut-off or disconnected. The residual energy of the blades of the pump spinning on the slowdown can be used to generate electricity to drive the fan that cools the pump. This configuration prevents the TEG from overheating and catastrophic damage.

In some embodiments, powering the at least one device 24 by the portion of the electricity generated by the at least one TEG 12 occurs during both the first operational mode (e.g., engine-on) and the second operational mode (e.g., engine-off). In some embodiments, such a system 10 can be configured during regular (engine-on) TEG operation as well as engine-off operation. For example, as discussed above, the at least one device 24 can be partially or wholly decoupled from the electrical components or subsystems, making the cooling circuit (including the at least one device 24) a self-contained subsystem. The electrically-powered cooling circuit can be powered by at least a part or portion of the electricity produced by the TEG, therefore decreasing the system complexity and increasing fault-tolerance. The electricity produced by the TEG can be used for a portion of the operation time of the system, or for substantially all of the time (e.g., always).

In some embodiments, the method 100 further comprises directing the at least one working fluid 18 through the at least one fluid conduit 16 while the portion of the electricity generated by the at least one TEG 12 is greater than a predetermined level. The method 100 can further comprise inhibiting the at least one working fluid 18 from flowing through the at least one fluid conduit 16 while the portion of the electricity generated by the at least one TEG 12 is less than the predetermined level. As discussed above, such a method can simplify the control system. For example, the at least one device 24 can be configured (i) to only operate (e.g., direct the at least one working fluid 18 through the at least one fluid conduit 16) when sufficient electric power is received and (ii) to not operate (e.g., to inhibit flow of the at least one working fluid 18 from flowing through the at least one fluid conduit 16) when less than the sufficient electric power for operation is received.

In some embodiments, the predetermined level is either an electric voltage level or an electric current level. Inhibiting the at least one working fluid 18 from flowing through the at least one fluid conduit 16 comprises automatically shutting off the at least one device 24 when the portion of the electricity generated by the at least one TEG 12 falls below the predetermined level.

Although certain configurations and examples are disclosed herein, the subject matter extends beyond the examples in the specifically disclosed configurations to other alternative configurations and/or uses, and to modifications and equivalents thereof. Thus, the scope of the claims appended hereto is not limited by any of the particular configurations described below. For example, in any method or process disclosed herein, the acts or operations of the method or process may be performed in any suitable sequence and are not necessarily limited to any particular disclosed sequence. Various operations may be described as multiple discrete operations in turn, in a manner that may be helpful in understanding certain configurations; however, the order of description should not be construed to imply that these operations are order dependent. Additionally, the structures, systems, and/or devices described herein may be embodied as integrated components or as separate components. For purposes of comparing various configurations, certain aspects and advantages of these configurations are described. Not necessarily all such aspects or advantages are achieved by any particular configuration. Thus, for example, various configurations may be carried out in a manner that achieves or optimizes one advantage or group of advantages as taught herein without necessarily achieving other aspects or advantages as may also be taught or suggested herein.

Discussion of the various configurations herein has generally followed the configurations schematically illustrated in the figures. However, it is contemplated that the particular features, structures, or characteristics of any configurations discussed herein may be combined in any suitable manner in one or more separate configurations not expressly illustrated or described. In many cases, structures that are described or illustrated as unitary or contiguous can be separated while still performing the function(s) of the unitary structure. In many instances, structures that are described or illustrated as separate can be joined or combined while still performing the function(s) of the separated structures.

Various configurations have been described above. Although the invention has been described with reference to these specific configurations, the descriptions are intended to be illustrative and are not intended to be limiting. Various modifications and applications may occur to those skilled in the art without departing from the true spirit and scope of the invention as defined in the appended claims.

What is claimed is:

1. A system comprising:
at least one thermoelectric generator configured to generate electricity in response to a temperature difference across at least a portion of the at least one thermoelectric generator;
at least one fluid conduit in thermal communication with the at least one thermoelectric generator, the at least one fluid conduit configured to have at least one working fluid flow through the at least one fluid conduit; and
at least one device configured to direct the at least one working fluid through the at least one fluid conduit, wherein the at least one device is powered by at least a portion of the electricity generated by the at least one thermoelectric generator.

2. The system of claim 1, wherein the at least one working fluid comprises a coolant fluid, the at least one fluid conduit comprises a coolant loop, and the at least one device is configured to circulate the coolant fluid through the coolant loop.

3. The system of claim 1, wherein the at least one working fluid and the at least one fluid conduit are configured to remove at least some waste heat from the at least one thermoelectric generator.

4. The system of claim 1, wherein the at least one fluid conduit is in thermal communication with a cold side of the at least one thermoelectric generator.

5. The system of claim 1, wherein the at least one device comprises at least one of the group consisting of: an electrically-powered pump, an electrically-powered fan, and an electrically-powered valve.

6. The system of claim 5, further comprising at least one control circuit configured to be powered by the at least one thermoelectric generator and to selectively provide power to the at least one device from the at least one thermoelectric generator.

7. The system of claim 5, wherein the at least one device is configured to respond to the portion of the electricity generated by the at least one thermoelectric generator being greater than a predetermined level by directing the at least one working fluid through the at least one fluid conduit, and wherein the at least one device is further configured to respond to the portion of the electricity generated by the at least one thermoelectric generator being less than the predetermined level by inhibiting the at least one working fluid from flowing through the at least one fluid conduit.

8. The system of claim 7, wherein the predetermined level is either an electric voltage level or an electric current level, and the at least one device is configured to automatically shut off when the portion of the electricity generated by the at least one thermoelectric generator falls below the predetermined level.

9. The system of claim 5, wherein the at least one device is configured to respond to at least one temperature of the at least one thermoelectric generator by directing the at least one working fluid through the at least one fluid conduit when the at least one temperature is greater than a predetermined value, and wherein the at least one device is configured to respond to the at least one temperature of the at least one thermoelectric generator by inhibiting the at least one working fluid from flowing through the at least one fluid conduit when the at least one temperature of the at least one thermoelectric generator is less than the predetermined level.

10. The system of claim 1, further comprising a heat source configured to provide heat that contributes to the temperature difference across the portion of the at least one thermoelectric generator.

11. The system of claim 10, wherein the heat source comprises at least one of the group consisting of: an internal combustion engine, an industrial manufacturing process, and a turbine.

12. The system of claim 10, wherein the heat source comprises an internal combustion engine, wherein the at least one working fluid and exhaust gas from the internal combustion engine generate the temperature difference across the portion of the at least one thermoelectric generator.

13. The system of claim 10, wherein the heat source generates heat during a first operational mode in which the heat source is on and the system comprises stored heat during a second operational mode in which the heat source is off.

14. The system of claim 13, wherein, during at least a portion of the second operational mode, the stored heat contributes to the temperature difference across the portion of the at least one thermoelectric generator, and the at least one device directs sufficient flow of the at least one working fluid through the at least one fluid conduit thereby preventing thermal damage to the at least one thermoelectric generator by the stored heat.

15. The system of claim 13, wherein the provided heat contributes to the temperature difference across the portion of the at least one thermoelectric generator during at least a portion of the first operational mode, and the at least one device is wholly powered by the portion of the electricity generated by the at least one thermoelectric generator.

16. A method of operating a system comprising at least one thermoelectric generator in thermal communication with a heat source and in thermal communication with at least one fluid conduit configured to have at least one working fluid flow through the at least one fluid conduit, wherein the heat source generates heat in a first operational mode and comprises stored heat during a second operational mode, the method comprising:
generating electricity using the at least one thermoelectric generator in response to a temperature difference across at least a portion of the at least one thermoelectric generator; and
powering at least one device by at least a portion of the electricity generated by the at least one thermoelectric generator, the at least one device configured to direct the at least one working fluid through the at least one fluid conduit.

17. The method of claim 16, wherein the heat source comprises an internal combustion engine that is on in the first operational mode and that is off in the second operational mode.

18. The method of claim 16, wherein, during at least a portion of the second operational mode, the stored heat contributes to the temperature difference across the portion of the at least one thermoelectric generator and directing the at least one working fluid through the at least one fluid conduit comprises removing heat from the at least one thermoelectric generator.

19. The method of claim 18, wherein removing heat from the at least one thermoelectric generator prevents catastrophic failure of the at least one thermoelectric generator due to overheating.

20. The method of claim 18, wherein the system comprises at least one battery, and powering the at least one device comprises reducing or eliminating use of electricity from the at least one battery to power the at least one device.

21. The method of claim 16, wherein powering the at least one device by the portion of the electricity generated by the at least one thermoelectric generator occurs during both the first operational mode and the second operational mode.

22. The method of claim 16, further comprising:
directing the at least one working fluid through the at least one fluid conduit when a temperature of the at least one thermoelectric generator is greater than a predetermined level; and
inhibiting the at least one working fluid from flowing through the at least one fluid conduit when the temperature of the at least one thermoelectric generator is less than the predetermined level.

23. The method of claim 16, further comprising:
directing the at least one working fluid through the at least one fluid conduit while the portion of the electricity generated by the at least one thermoelectric generator is greater than a predetermined level; and
inhibiting the at least one working fluid from flowing through the at least one fluid conduit while the portion of the electricity generated by the at least one thermoelectric generator is less than the predetermined level.

24. The method of claim 23, wherein the predetermined level is either an electric voltage level or an electric current level, and inhibiting the at least one working fluid from flowing through the at least one fluid conduit comprises automatically shutting off the at least one device when the portion of the electricity generated by the at least one thermoelectric generator falls below the predetermined level.
